(19) United States
(12) Patent Application Publication
(10) Pub. No.: US 2016/0219748 A1
(43) Pub. Date: Jul. 28, 2016

(54) DOUBLE-RACK STORAGE MEDIA CHASSIS STRUCTURE

(71) Applicant: AIC INC., Taoyuan Hsien (TW)

(72) Inventors: Kun-Sheng TSAI, Taoyuan Hsien (TW); Wei-Shih WU, Taoyuan Hsien (TW); Yong-Cong CHEN, Taoyuan Hsien (TW)

(21) Appl. No.: 14/603,356

(22) Filed: Jan. 22, 2015

(51) Int. Cl. H05K 7/14

(52) U.S. Cl. CPC H05K 7/1489

(57) ABSTRACT

A double-rack storage media chassis structure includes a chassis (100), two storage media modules (200) and two slide modules (300). The chassis (100) includes a partition frame (110) and two storage spaces (120) formed on both sides of the partition frame (110) respectively. Each storage media module (200) accommodated in each respective storage space (120) includes a tray frame (210) and storage media (220). The tray frame (210) includes a side panel (230) and an access opening (240) disposed opposite to the side panel (230). Each access opening (240) of each storage media module (200) is arranged correspondingly. Each slide module (300) includes a first slide assembly (310) on a side panel of the chassis (100) and a second slide assembly (320) on a side panel (230) of the tray frame (210). The storage media can be pulled out from inner sides of the two storage media modules conveniently.

### FIELD OF THE INVENTION

The present invention relates to a chassis structure, and more particularly to a double-rack storage media chassis structure that facilitates users to remove storage media from inner sides of two storage media modules.

### BACKGROUND OF THE INVENTION

Server is a core computer for serving each computer in a network system, and also providing necessary functions such as storage and printing services to network users, while allowing users to share resources in a network environment. The basic architecture of a server is substantially the same as that of a personal computer and composed of a central processing unit (CPU), a memory and an input/output (I/O) device connected internally by a bus, and a Northbridge chip is provided for connecting the CPU and memory and a Southbridge chip is provided for connecting the I/O device.

The dimensions of the chassis generally adopt industrial standards such as 22 U to 48 U. However, the height U of the chassis may be changed flexibly by users as needed for storing network equipments such as server, hub, and disk array cabinets. After being arranged properly in the server, the aforementioned network equipments are arranged in rows and installed adjacent to each other, and then disposed in a factory or engine room. Most of the server cabinets are disposed against a wall, but there is an issue of running out of space or causing inconvenience to operation.

For servers with removable hard disk modules, the hard disk modules may not be plugged in or removed easily from both left and right sides of the chassis or blocked by the wall, if the chassis is placed in a limited space, and thus the hard disk modules cannot be installed, replaced or repaired easily.

In view of the aforementioned problems of the prior art, the inventor of the present invention based on years of experience in the related industry to conduct extensive researches and experiments, and finally designed and developed a double-rack storage medial chassis structure to overcome the problems of the prior art.

### SUMMARY OF THE INVENTION

It is a primary objective of the present invention to provide a double-rack storage media chassis structure for users to move storage media out from inner sides of two storage media modules without being limited by the occasion of use, so as to improve the convenience of operation.

To achieve the aforementioned objective, the present invention provides a double-rack storage media chassis structure, comprising a chassis, two storage media modules and two slide modules. The chassis includes a partition frame and two storage spaces. The storage spaces are formed on both sides of the partition frame respectively. Each storage media module is accommodated in each respectively storage space. Each storage media module includes a tray frame and a plurality of storage media. The tray frame has a side panel and an access opening arranged opposite to the side panel. Each storage medium is stacked into or removed from the tray frame sequentially through the access opening, wherein each access opening of each storage media module is arranged correspondingly. Each slide module includes a first slide assembly installed on a side panel of the chassis, and a second slide assembly installed on the side panel of the tray frame.

The present invention further has the following effects: The double-rack storage media chassis structure is composed of two parallel storage media modules, and each storage media module is provided for accommodating a plurality of storage media, so that the double-rack storage media module can accommodate a greater quantity of storage media, so as to improve the storage capacity and expandability of the chassis. Each storage media module is fixed to the second slide assembly of the chassis through the slide module and stropped by an elastic plate for limiting the position of the storage media module and preventing the storage medium from being pulled excessively or falling out accidentally. When the storage media module is moved with respect to the chassis, a cable connected to each storage medium is protected by a chain structure and moved or curled with the chain structure, and thus the invention can protect the cable and improve the degree of freedom of the movement.

### BRIEF DESCRIPTION OF THE DRAWINGS

FIG. 1 is an exploded view of a double-rack storage media chassis structure of the present invention;

FIG. 2 is a partial exploded view of a single storage media module of the present invention;

FIG. 3 is a perspective view of a double-rack storage media chassis structure stored in a chassis according to the present invention;

FIG. 4 is a schematic view of pulling two storage media modules out from a chassis according to the present invention;

FIG. 5 is a planar view of pulling a single storage media module out from a chassis according to the present invention, wherein a chain structure is moved or curled; and

FIG. 6 is a schematic view of pulling a single storage media module out from a chassis and taking a storage medium out from an access opening according to the present invention.

### DESCRIPTION OF THE PREFERRED EMBODIMENTS

The technical contents of the present invention will become apparent with the detailed description of preferred embodiments accompanied with the illustration of related drawings as follows. It is noteworthy that same numerals are used for representing same respective elements in the drawings.

The present invention provides a double-rack storage media chassis structure capable of improving the convenience of operation. The storage medium includes but not limited to a hard disk, an optical disk or any other appropriate storage medium.

The above and other objects, features and advantages of the present invention will become apparent from the following detailed description taken with the accompanying drawing. Only some embodiments of the present invention have been illustrated in the drawings, but it should be pointed out that many other modifications are conceivable within the scope of the following claims.

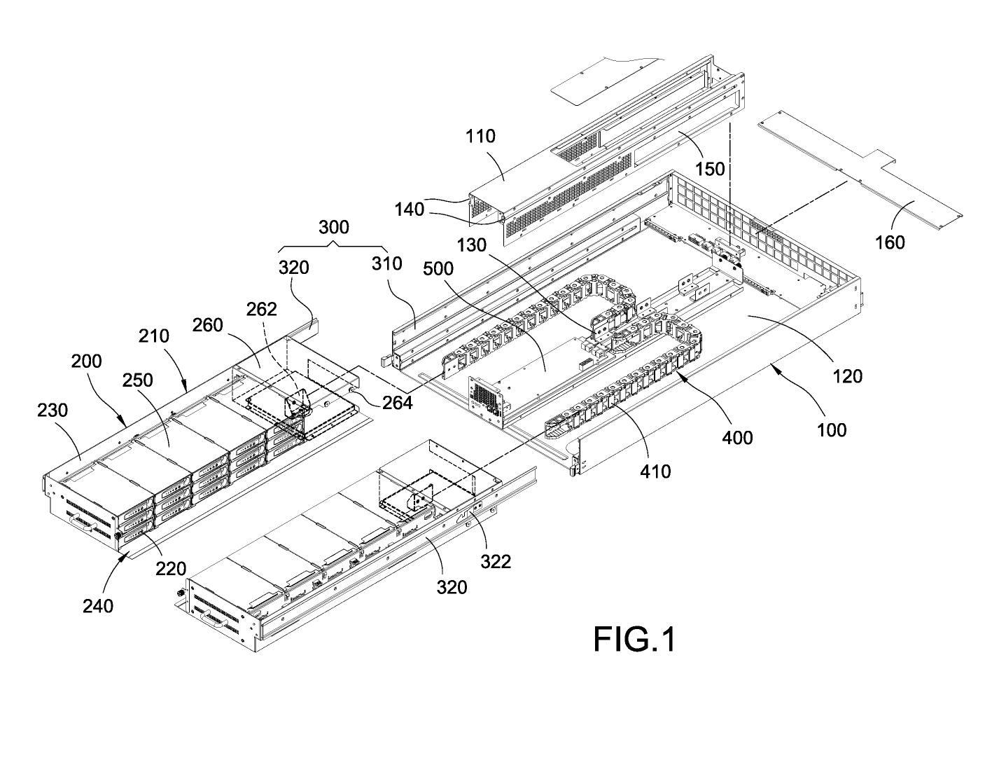

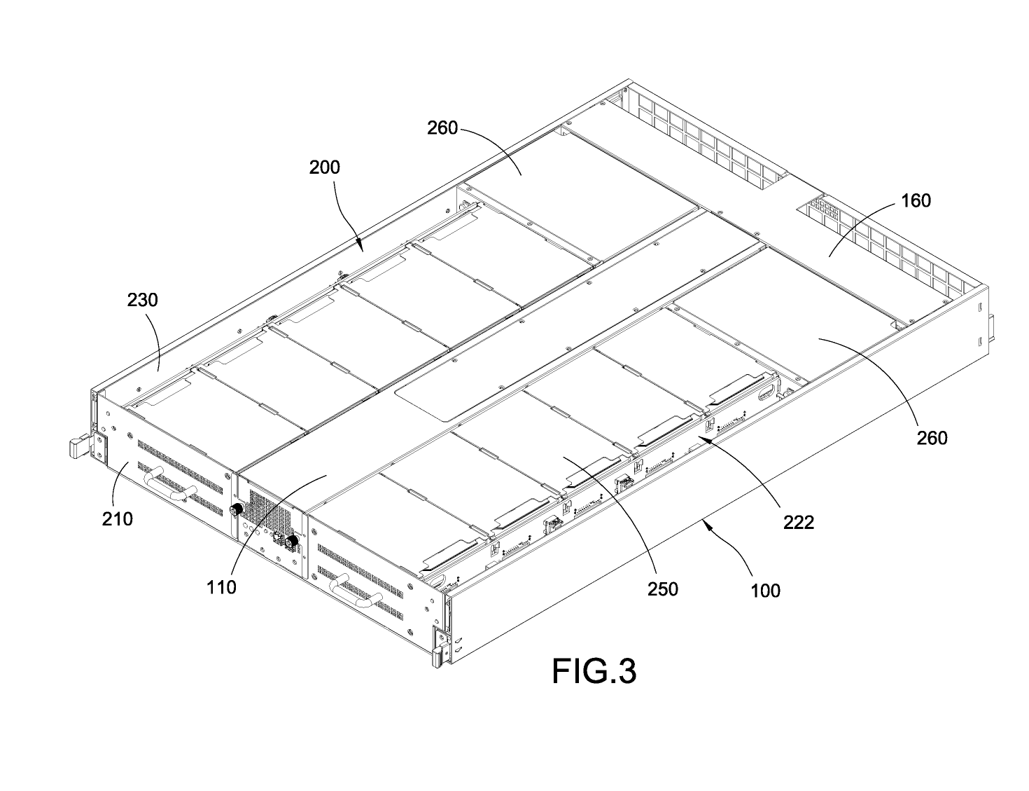

With reference to FIGS. 1, 2 and 3 for a double-rack storage media chassis structure of the present invention, the double-rack storage media chassis structure comprises a chassis 100, two storage media modules 200 and two slide modules 300. The chassis 100 includes a partition frame 110 and two storage spaces 120. The storage spaces 120 are formed on both sides of the partition frame 110 respectively. Each storage media module 200 is accommodated in each respective storage space 120. Each storage media module 200 includes a tray frame 210 and a plurality of storage media 220. The tray frame 210 has a side panel 230 and an access opening 240 arranged opposite to the side panel 230. Each storage medium 220 is stacked into or removed from the tray frame 210 through the access opening 240, wherein each access opening 240 of each storage media module 200 is installed correspondingly. Each slide module 300 includes a first slide assembly 310 installed on a side panel of the chassis 100 and a second slide assembly 320 installed on side panel 230 of the tray frame 210.

In this preferred embodiment, each storage media module 200 further includes a storage media combination frame 250 for stacking each of the storage media 220, and the storage media combination frame 250 is installed to the tray frame 210 by riveting. Each storage medium 220 is stacked into or removed from the storage media combination frame 250 sequentially through the access opening 240. Therefore, the storage medium 220 can be accessed from two opposite inner sides of the two storage media modules 200 (or through the access opening 240) without being limited by the occasion of use, particularly when it is necessary to installed, remove or repair a storage medium 220.

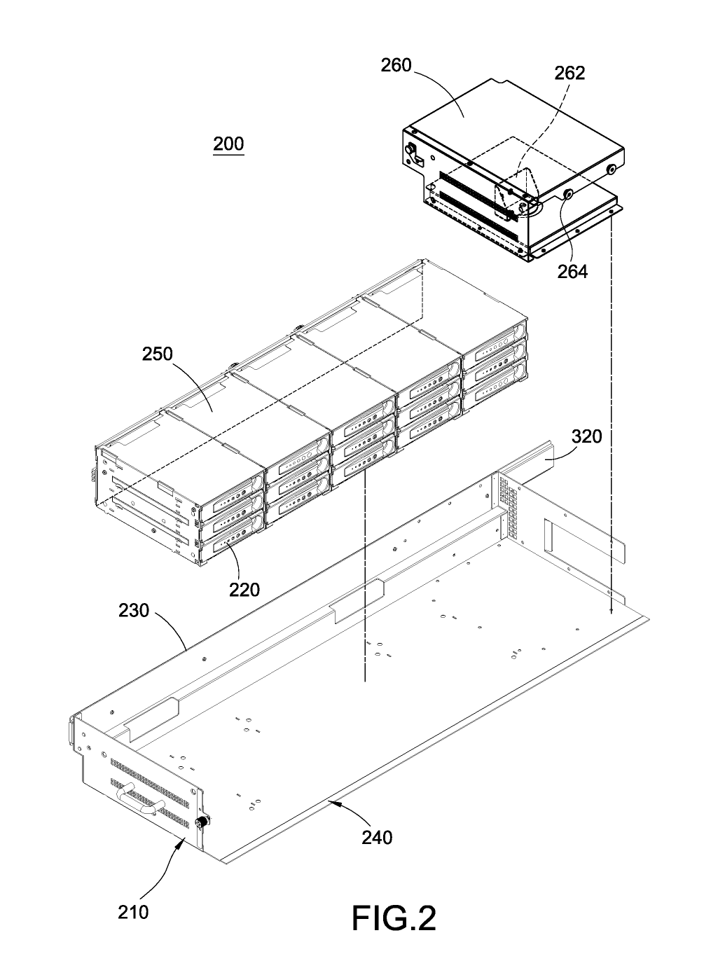

In FIGS. 1 and 2, each storage media combination frame 250 can carry 15 storage media 220, and the double-rack storage media module 200 can carry 30 storage media 220, so that the quantity of storage media 220 may be increased, and the storage capacity and expandability of a single chassis 100 can be improved.

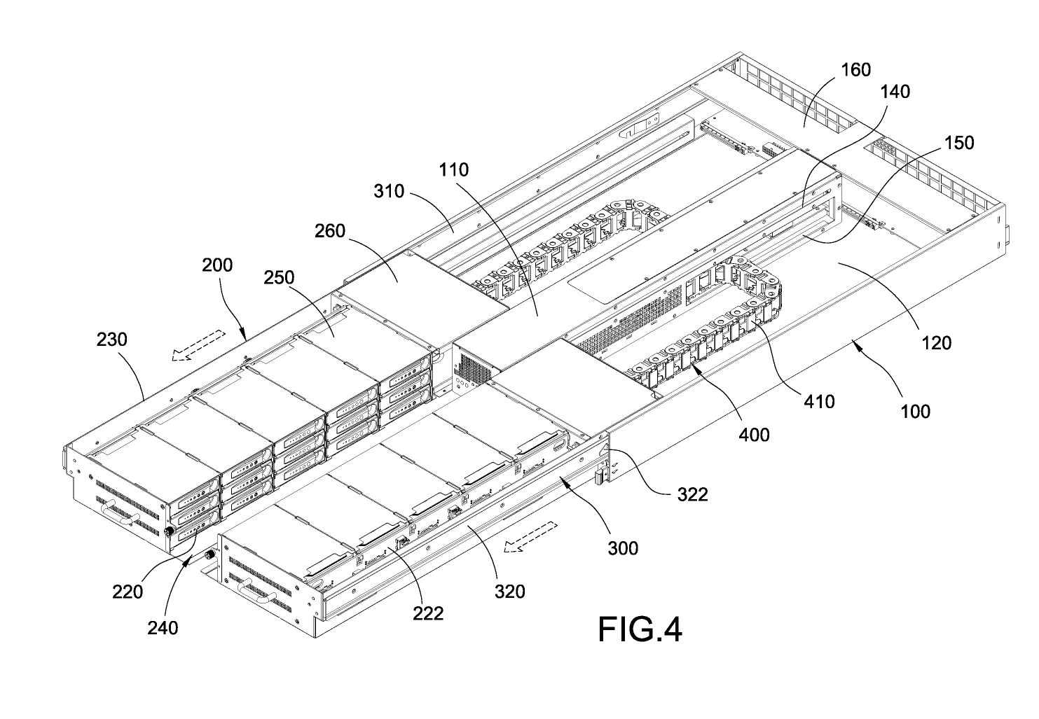

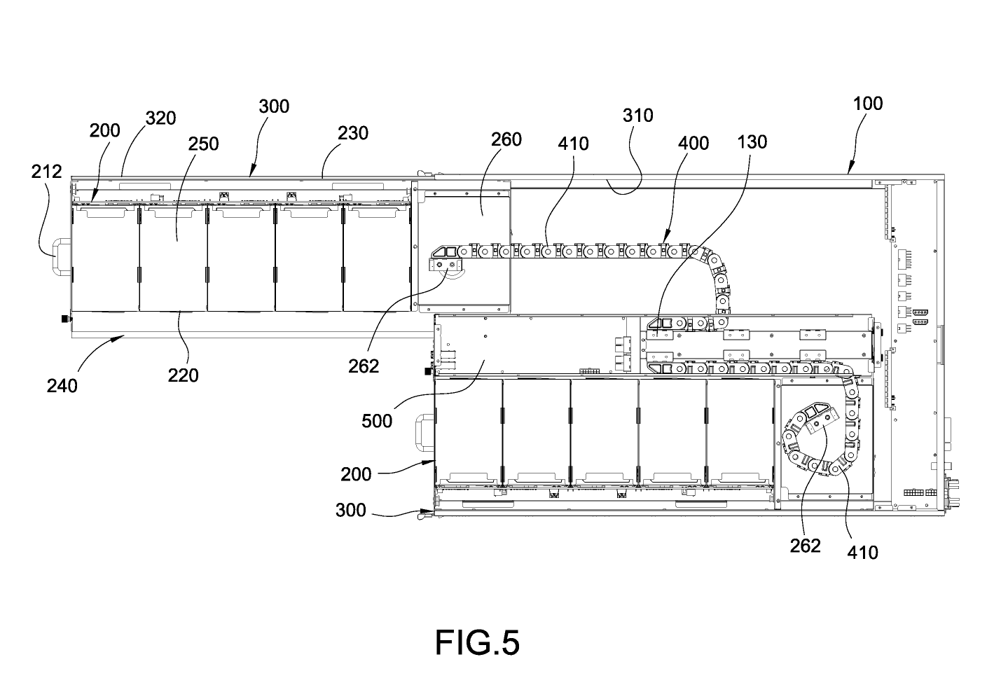

In FIGS. 4 and 5, each storage media module 200 further includes a chain structure 400 coupled to each tray frame 210 and a framework 260 for accommodating the chain structure 400. The framework 260 is installed at the tray frame 210 and coupled adjacent to the storage media combination frame 250. The chain structure 400 can limit the position of the tray frame 210 in the chassis 100 and operate together with the slide module 300 and the second slide assembly 320 to prevent the tray frame 210 from being pulled excessively of falling out accidentally. The chain structure 400 is formed by connecting a plurality of pivots 410. The partition frame 110 further includes a fixing portion 130 coupled to an end of the chain structure 400, and the framework 260 includes a pivot bracket 262 coupled to the other end of the chain structure 400.

In FIG. 4, the partition frame 110 includes a central control module 500 disposed at a front end of the partition frame 110 for monitoring and controlling the access status of each storage medium 220 or other operations. The rear end of the partition frame 110 is provided for accommodating a portion of the chain structure 400 or other cables (not shown in the figure). In addition, the storage media combination frame 250 for carrying each storage medium 220 electrically connects each storage medium 220 through a single backplane 222, so that a cable (not shown in the figure) of a single backplane 222 is passed into each pivot 410 to connect the central control unit 500. Therefore, the single backplane 222 is installed at a rear side of the storage media combination frame 250 to facilitate the integration and save unnecessary wiring. With the protection of the chain structure 400, the backplane 222 is connected to the central control module 500 to provide a neat arrangement of cables (not shown in the figure) and a good protection in the process of moving the tray frame 210.

In FIG. 5, when the storage media module 200 is pulled out from the chassis 100 by a handle 212, the pivots 410 of the chain structure 400 are pulled out one by one from an open slot (not labeled in the figure) of the partition frame 110, and a cable (not shown in the figure) connected to the single backplane 222 is moved and curled by the chain structure 400. Now, the chain structure 400 will limit the position of the tray frame 210 with respect to the chassis 100. When the storage media module 200 is pushed back and stored in the storage space 120 of the chassis 100, each pivot 410 of the chain structure 400 will enter into the open slot (not labeled in the figure) until some of the pivots 410 are curled and stored in the framework 260. To facilitate the pivots 410 to be stored in the framework 260, the pivot bracket 262 includes a rotating chute (not labeled in the figure) for curling each pivot 410 and storing the pivot 410 into the framework 260 more easily.

In FIGS. 1 and 4, a guide slot 140 is formed separately on both sides of the partition frame 110 and disposed precisely above the open slot 150. The storage media module 200 further includes a guide element 264 installed to a side of the framework 260 and provided for installing to the guide slot 140. In a preferred embodiment as shown in FIG. 1, it is preferably to have two guide elements 264, so that the tray member 210 can slide stably in the guide slot 140. Wherein, the guide element 264 is preferably a pulley. With the guide element 264 installed on a side of the framework 260, the guide slots 140 formed on both sides of the partition frame 110 respectively, and the first slide assembly 310 and the second slide assembly 320 installed on two side panels of the chassis 100 respectively, each tray frame 210 can slide in the storage space 120 of the chassis 100 freely. In addition, each storage media module 200 can store more storage media 220, so that the chassis 100 further includes a reinforced baffle 160 to reinforce the structure of the chassis 100.

In a preferred embodiment as shown in FIGS. 1 and 4, the reinforced baffle 160 is coupled to two side panels of the chassis 100 and a side panel at the bottom of the chassis 100. In addition, the guide element 264 installed to the framework 260 and the partition frame 110 installed with the guide slot 140 are preferably reinforced metal pieces to enhance the rigidity of the two slide modules 300.

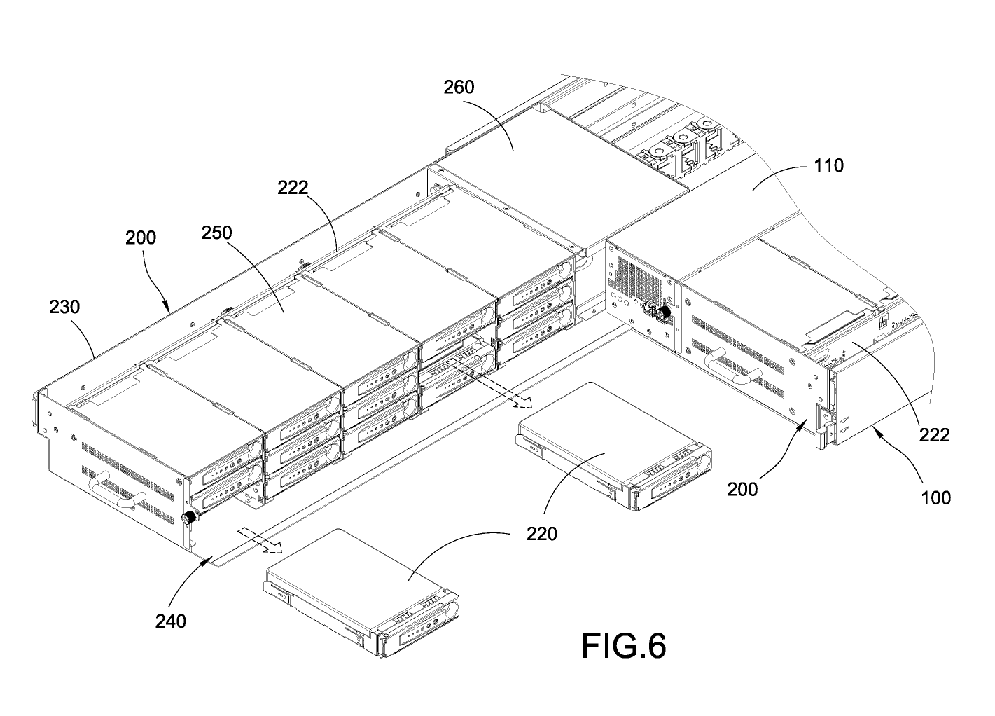

In FIG. 6, the single tray frame 210 can be pulled out from the chassis 100 through the access opening 240, and then the storage media 220 in the double-rack storage media module 200 can be installed, replaced or repaired one by one as needed. In FIG. 4, the second slide assembly 320 further includes an elastic plate 322 installed between the first slide assembly 310 and the second slide assembly 320 for stopping the tray frame 210 and preventing it from returning to the storage space 120. With such arrangement of the elastic plate 322, the position of the storage media module 200 is limited to prevent the storage medium 200 from being pulled excessively or falling out.

While the invention has been described by means of specific embodiments, numerous modifications and variations could be made thereto by those skilled in the art without departing from the scope and spirit of the invention set forth in the claims.

What is claimed is:

1. A double-rack storage media chassis structure, comprising:
a chassis (100), including a partition frame (110) and two storage spaces (120) disposed on both sides of the partition frame (110) respectively;
two storage media modules (200), accommodated in the two storage space (120) respectively, and each storage media module (200) including a tray frame (210) and a plurality of storage media (220), and the tray frame (210) having a side panel (230) and an access opening (240) arranged opposite to the side panel (230), and each storage medium (220) being stacked into or removed from the tray frame (210) sequentially through the access opening (240), wherein each access opening (240) of each storage media module (200) is arranged correspondingly; and
two slide modules (300), each including a first slide assembly (310) installed on a side panel of the chassis (100), and a second slide assembly (320) installed on the side panel (230) of the tray frame (210).

2. The double-rack storage media chassis structure of claim 1, wherein each storage media module (200) further includes a storage media combination frame (250) installed on the tray frame (210), and each storage medium (220) is stacked into or removed from the storage media combination frame (250) sequentially through the access opening (240).

3. The double-rack storage media chassis structure of claim 1, wherein each storage media module (200) further includes a chain structure (400) coupled to each tray frame (210), and a framework 260 for accommodating the chain structure (400), and the framework (260) is disposed at the tray frame (210) and coupled adjacently to the storage media combination frame (250), and the chain structure (400) is capable of limiting the position of the tray frame (210) in the chassis (100).

4. The double-rack storage media chassis structure of claim 3, wherein the chain structure (400) is formed by connecting a plurality of pivots (410), and the partition frame (110) further includes a fixing portion (130) coupled to an end of the chain structure (400), and the framework (260) includes a pivot bracket (262) coupled to the other end of the chain structure (400).

5. The double-rack storage media chassis structure of claim 4, wherein the partition frame (110) further includes an open slot (150) provided for each pivot (410) to movably curl in the open slot (150) and the storage space (120) to improve the degree of freedom.

6. The double-rack storage media chassis structure of claim 3, wherein the partition frame (110) includes a guide slot (140) formed on both sides of the partition frame (110) separately and above the open slot (150), and the storage media module (200) further includes a guide element (264) installed on a side of the framework (260) and provided for installing to the guide slot (140).

7. The double-rack storage media chassis structure of claim 3, wherein the framework (260) is a reinforced metal piece.

8. The double-rack storage media chassis structure of claim 6, wherein the guide element (264) is a pulley.

9. The double-rack storage media chassis structure of claim 6, wherein the framework (260) is a reinforced metal piece.

10. The double-rack storage media chassis structure of claim 1, wherein the partition frame (110) further comprises a central control module (500) for monitoring and controlling an access status of each storage medium (220).

11. The double-rack storage media chassis structure of claim 1, further comprising a reinforced baffle (160) coupled to both sides of the chassis (100) and a side panel at the bottom of the chassis (100) separately.
